(19) United States
(12) Patent Application Publication
(10) Pub. No.: US 2026/0255524 A1
(43) Pub. Date: Aug. 27, 2026

(54) CABLE MANAGEMENT BRACKET

(71) Applicant: E2 Optics, LLC, Englewood, CO (US)

(72) Inventor: Andrew C. Herman, Omaha, NE (US)

(21) Appl. No.: 19/550,669

(22) Filed: Feb. 26, 2026

Related U.S. Application Data
(60) Provisional application No. 63/764,251, filed on Feb. 27, 2025.

(51) Int. Cl. H05K 7/14; H05K 5/02

(52) U.S. Cl. CPC H05K 7/1491; H05K 5/0247

(57) ABSTRACT

A bracket for managing/dressing cables includes a base and multiple rings. The base of the bracket is configured to couple to electrical equipment. Each ring defines an opening configured to receive a respective group of cables, and the rings separate the respective groups of cables from one another to facilitate managing the groups of cables.

### CROSS-REFERENCE

This patent application claims priority to and the benefit of U.S. Provisional Patent Application No. 63/764,251, entitled “CABLE MANAGEMENT BRACKET,” filed February 27, 2025, and hereby incorporated by reference in its entirety for all purposes.

### TECHNICAL FIELD

The present disclosure relates to a bracket for cable management and dressing.

### BACKGROUND

Cables and wires are used to electrically and/or operably interconnect various electrical components. For example, a cable may exchange data between electrical components to enable the electrical components to communicate with one another. Cables are becoming increasingly prevalent as technology becomes more digitized. In some implementations, such as in data centers, multiple cables are arranged in close proximity to one another over ever increasing distances. In such cases, it is important to route cables in a manner that efficiently utilizes a space occupied by the cables and effectively organizes the cables. It is also important that cable arrangements do not cause cables to interfere with one another and allow cables to be distinguished from one another, such as to ensure that a cable is desirably coupled to a particular electrical component.

### SUMMARY

Disclosed are techniques related to managing and dressing cables. More specifically, a bracket is used to bundle cables into groups while separating individual groups of cables from one another. As a result, the bracket may help differentiate groups of cables from one another to enable the cables to be better organized. Moreover, with the bracket presented herein, each group of cables may be secured in an efficient manner (e.g., to occupy a small amount of space), but without tightly retaining cables in a manner that prevents the cables from being easily removed from the bracket and/or adjusted with respect to the bracket, e.g., via pulling from a distance away from the bracket.

In some embodiments, a bracket includes a base configured to be removably coupled to electrical equipment and a plurality of rings cooperatively defining a plurality of openings configured to separate cables into groups. Each ring of the plurality of rings includes a fixed portion extending from the base and a flexible portion extending from the fixed portion and configured to flex relative to the fixed portion to adjust a size of an opening of the plurality of openings.

In some embodiments, a system includes electrical equipment comprising an electrical component and a bracket configured to be removably coupled to the electrical equipment. The bracket has a plurality of rings that each include a fixed portion and a flexible portion extending from the fixed portion such that the fixed portion and the flexible portion cooperatively define an opening configured to receive a cable for coupling to the electrical component. The flexible portion is configured to flex relative to the fixed portion to adjust a size of the opening.

In some embodiments, a bracket for managing cables includes a base configured to secure to electrical equipment, a first fixed portion extending from the base, a second fixed portion extending from the base, and a flexible portion extending from the first fixed portion toward the second fixed portion such that the first fixed portion, the second fixed portion, and the flexible portion cooperatively define an opening configured to receive cables. The flexible portion is configured to flex relative to the first fixed portion to adjust a size of the opening.

These and other advantages and features will become evident in view of the drawings and detailed description.

### BRIEF DESCRIPTION OF THE DRAWINGS

To complete the description and in order to provide for a better understanding of the present disclosure, a set of drawings is provided. The drawings form an integral part of the description and illustrate implementations of the present disclosure, which should not be interpreted as restricting the scope of the disclosure, but just as an example of how the disclosure can be carried out. The drawings comprise the following figures:

FIG. 1 illustrates a portion of an electrical equipment space that includes brackets for managing and dressing cables, according to embodiments of the present disclosure;

FIG. 2 is a front perspective view of electrical equipment that includes brackets for managing and dressing cables, according to embodiments of the present disclosure;

FIG. 3 is a front perspective view of another segment of electrical equipment that includes a bracket for managing and dressing cables, according to embodiments of the present disclosure;

FIGS. 4A-4C and 5A-5C are each a top perspective view of a bracket usable for managing and dressing cables, according to embodiments of the present disclosure;

FIGS. 6A and 6B each provide a cross-sectional view of a bracket usable for managing and dressing cables, according to embodiments of the present disclosure;

FIGS. 7A-7F each illustrate a bracket coupled to electrical equipment in a first configuration for managing and dressing cables, according to embodiments of the present disclosure;

FIGS. 8A-8C each illustrate a bracket coupled to electrical equipment in a second configuration for managing and dressing cables, according to embodiments of the present disclosure;

FIG. 9 is a top perspective view of electrical equipment that includes a bracket for managing and dressing cables, according to embodiments of the present disclosure;

FIGS. 10A-10D each illustrate a bracket coupled to a mount for managing and dressing cables, according to embodiments of the present disclosure;

FIG. 11 is a top perspective view of another bracket usable for managing and dressing cables, according to embodiments of the present disclosure;

FIGS. 12A-12D each provide a cross-sectional view of the bracket of FIG. 11, according to embodiments of the present disclosure; and

FIG. 13 is a side perspective view of a portion of electrical equipment to which the bracket of FIG. 11 may attach, according to embodiments of the present disclosure.

### DETAILED DESCRIPTION

Generally, this application is directed to managing, dressing, routing, organizing, and otherwise arranging cables. Cables are used to electrically and/or operably interconnect various electrical components to one another, such as to enable electrical components to communicate with one another. A cable may extend a substantial length, such as several meters or even several miles, and may therefore interconnect electrical components that are not positioned adjacent to one another. Unfortunately, increasing usage of cables can render cable management correspondingly more difficult. For example, it may be difficult to route multiple cables with respect to one another to avoid entanglement, to distinguish cables from one another, or to otherwise efficiently utilize the space in which the cables are positioned.

Therefore, embodiments of the present disclosure are directed to a bracket for managing/dressing cables. The bracket includes a base and multiple rings. The base of the bracket is configured to couple to electrical equipment, such as a housing and/or a dedicated cable management frame, to secure the bracket to the electrical equipment. Meanwhile, each ring defines an opening configured to receive a respective group of cables. The rings separate the respective groups of cables from one another to divide the cables into groups, which may be more easily organized (e.g., routed). Thus, the bracket facilitates cable management/dressing, such as to route along electrical equipment in a desirable manner.

In some embodiments, each ring includes a flexible portion that is configured to flex to make its opening more accessible during cable routing, e.g., to allow a group of cables to be inserted into and/or removed from the opening. The flexible portion is also urged to close to retain the group of cables in the opening. Thus, the rings ease cable installation, organization, and distribution, among other tasks, during management/dressing. The openings, however, are configured to closely retain a group of cables without tightly gripping the group of cables. Thus, the flexible portions are not biased to compressively engage a group of cables installed in an opening; instead, the flexible portions are biased to rest positions in which the flexible portions enclose an opening. With this arrangement, a group of cables may be held together in an efficient amount of space, but may be held “loose enough” that the group of cables, or at least a subset thereof, can be pulled/moved through an opening in the bracket, e.g., when moving the cable for installation, such as to couple to an electrical component. Thus, the bracket helps organize the cables while still enabling the cables to be adjusted with respect to the bracket while extending through the openings of the bracket.

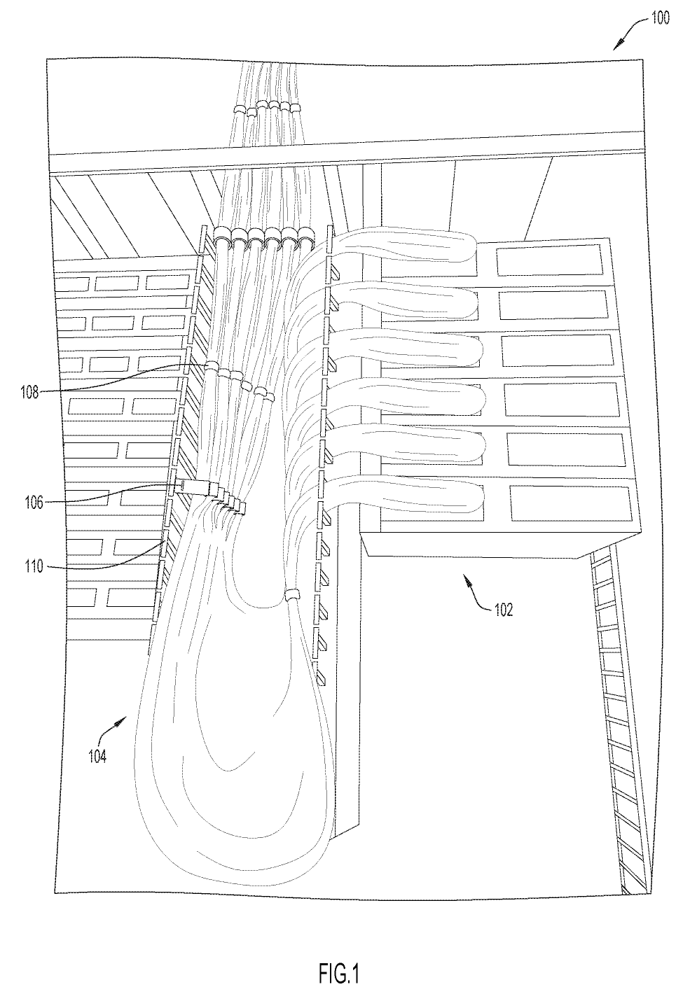

FIG. 1 illustrates a portion of an electrical equipment space 100, such as a server room, a communications room, a control room, and/or any portion of a data center, which contains various interconnected electrical components 102. For example, such electrical components 102 may include a server, a switch, a router, a power source, and so forth. Cables 104 are utilized to electrically and/or operably interconnect the electrical components 102 to one another, such as to enable data/power exchange therebetween.

The quantity of cables 104 positioned at a part of the electrical equipment space 100 can depend on the quantity of electrical components 102 disposed therein, but in general, several cables 104 extend adjacent to one another to efficiently utilize the electrical equipment space 100. In other words, the density of cables 104 at the depicted electrical equipment space 100 is high to reduce an overall physical footprint occupied by the cables 104. The brackets 106 of the present application are used to help route the cables 104 and improve an ease of organizing the cables 104. For example, each bracket 106 may bundle certain cables 104 into different groups and separate the groups of cables 104 from one another. Consequently, each bracket 106 may divide a large quantity of cables 104 into smaller, more manageable subsets that can be more easily distinguished from one another and handled for desirable routing, such as to avoid entangling and interfering with one another.

In addition to the brackets 106, straps 108 (e.g., hook-and-loop fasteners) can supplement the brackets 106 and further separate the cables 104 into their respective groups. However, it should be noted that the bracket embodiments disclosed herein may provide certain advantages over usage of the straps 108 alone. As an example, while individual straps 108 are used to bundle each respective group of cables 104, a single bracket 106 may separate cables 104 into multiple groups. In other words, the brackets 106 may more efficiently separate the cables 104 into groups.

As another example, a bracket 106 may be more rigidly fixed and may therefore be easier to position and implement as desired. For instance, a bracket 106 may be fixed to a component 110 other than the cables 104 to restrict movement of the bracket 106. In contrast, a strap 108 may be coupled to corresponding cables 104 and may be subject to slipping along the cables 104. In fact, to try to prevent sliding, straps 108 are often tightly installed around a bundle or group of cables 104. Then, it becomes difficult to move the cables 104 through this strap 108 without disconnecting the strap 108. Brackets 106 fixed to a component 110 other than the cables 104, on the other hand, maintain a desired spacing between cable bundles/dressings. For this reason, the bracket 106 may more securely hold the cables 104 as desired. Furthermore, it may be difficult to controllably adjust attachment of a strap 108 with respect to a cable 104. By way of example, the strap 108 may be loosened and opened in order to secure a cable 104 with a strap 108 or to detach a cable 104 from a strap 108. However, sufficiently opening the strap 108 to enable the cable 104 to be secured to or detached from the strap 108 may potentially cause the strap 108 to be detached from other cables 104. That is, it may be difficult, labor-intensive, and/or time-consuming to selectively secure or detach a particular cable 104 relative to the strap 108 without affecting securement of the strap 108 to another cable 104.

Nevertheless, brackets 106 and straps 108 may be utilized in conjunction with one another, such as at different parts of the cables 104 along their lengths, to help manage and dress the cables 104. In a specific example, a bracket 106 may be primarily used to manage cables 104 along their lengths when a component 110 is available for the bracket 106 to be secured or removably coupled thereto, whereas straps 108 may be used to manage cables 104 at areas where a component 110 is not available. By limiting the usage or quantity of straps 108, cables 104 may be more easily/efficiently managed. For example, when cables 104 extend over long distances (perhaps as far as a mile or more), multiple straps 108 connected to one of those cables 104 may be removed to enable the cable 104 to be moved, rendering the process quite tedious and cumbersome. However, critically, because the brackets 106 presented herein can be maintained in a specific location by fixing the brackets 106 to components 110 other than the cables 104, the brackets 106 need not be tightly wrapped around a group of cables 104. Instead, the bracket 106 may “loosely” hold a group of cables 104 in an efficient amount of space that allows the cable 104 to be pulled through an opening in the bracket 106, e.g., when removing the cable 104 from an installation, such as for replacement.

In some embodiments, the bracket 106 is configured to readily couple to an existing component 110, such as an already implemented support structure/frame, in the electrical equipment space 100. Thus, the bracket 106 may be implemented without having to install a separate (e.g., dedicated) component for positioning the bracket to organize cables 104. For this reason, the bracket 106 may be easy to use with low barriers of cost and/or labor. The following figures illustrate example applications of the bracket 106, as well as different configurations of bracket implementations.

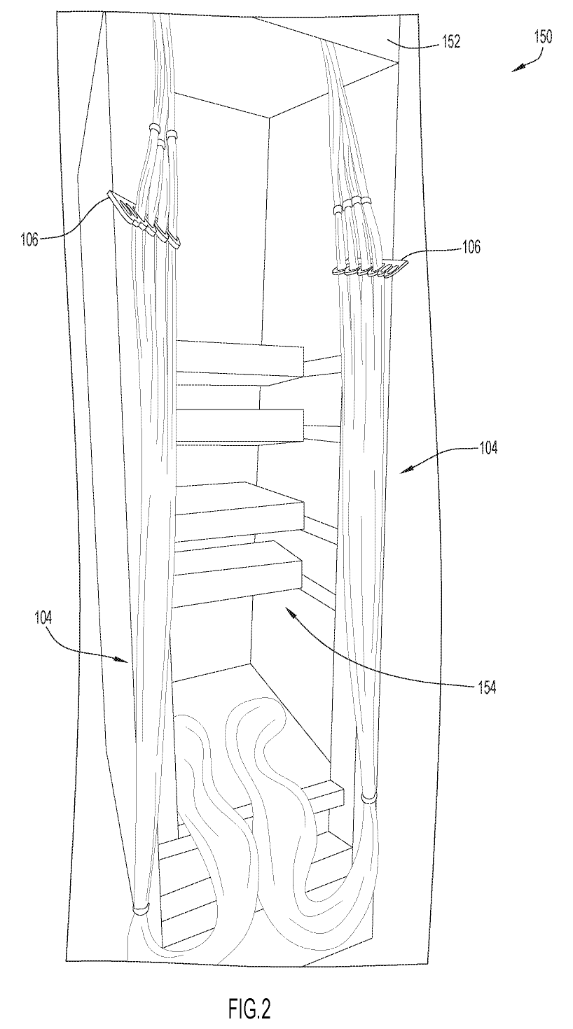

FIG. 2 is a front perspective view of electrical equipment 150 that utilizes the brackets 106 for managing/dressing cables 104. The electrical equipment 150 includes a housing 152, as well as various electrical components 154 disposed in the housing 152 and at least partially shielded by and collected within the housing 152. By way of example, the electrical equipment 150 may include a server rack that contains multiple servers, and cables 104 may be connected to each of the servers in a one-to-one relationship (e.g., to electrically couple the server to another electrical component). This example, however, is not intended to be limiting, and the bracket 106 presented herein may be utilized with any equipment connected in any manner (e.g., with many cables 104 per piece of equipment arrangements). In this arrangement, each bracket 106 is coupled (e.g., fixed) to the housing 152 and is configured to route respective groups of cables 104 along sides of the housing 152.

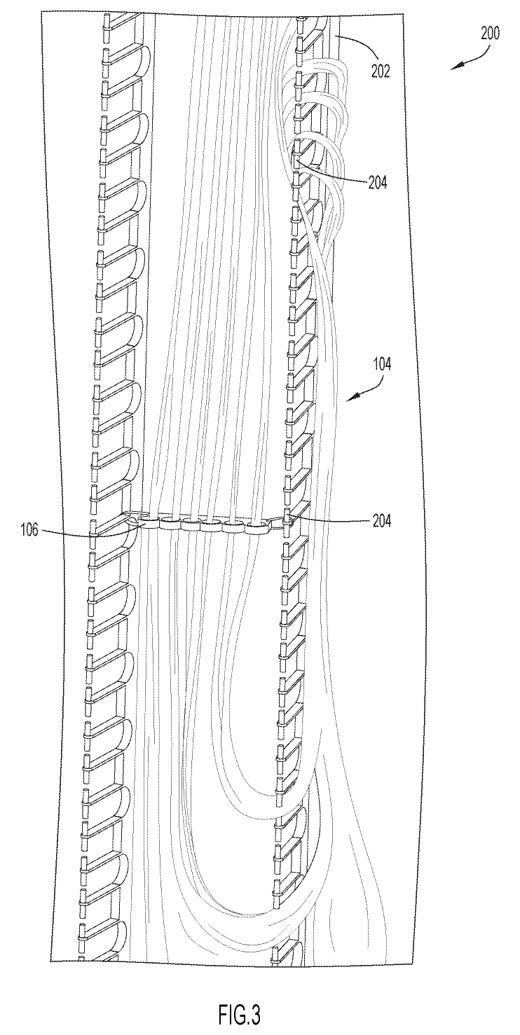

FIG. 3 is a side perspective view of electrical equipment 200 that utilizes the brackets 106 for managing/dressing cables 104. The electrical equipment 200 includes a cable management frame 202 (e.g., a vertical cable manager, a horizontal cable manager), which includes a feature 204, such as a finger, a rail, a slot, a channel, and the like, usable to help route cables 104. For instance, the feature 204 may be used to help route/hold a portion of the cables 104. The cable management frame 202 may supplement a housing (e.g., the housing 152) that contains electrical components (e.g., the electrical components 102) electrically coupled to the cables 104 or be formed integrally therewith. That is, the cable management frame 202 may be dedicated to, as an example, routing cables 104 rather than to enclosing the electrical components. Each bracket 106 is configured to couple to the cable management frame 202. In some embodiments, a bracket 106 is configured to couple to an existing feature, such as any of the aforementioned features 204 used for routing cables 104, of the cable management frame 202. In additional or alternative embodiments, a bracket 106 is configured to couple to a dedicated feature for mounting the bracket 106 to the cable management frame 202.

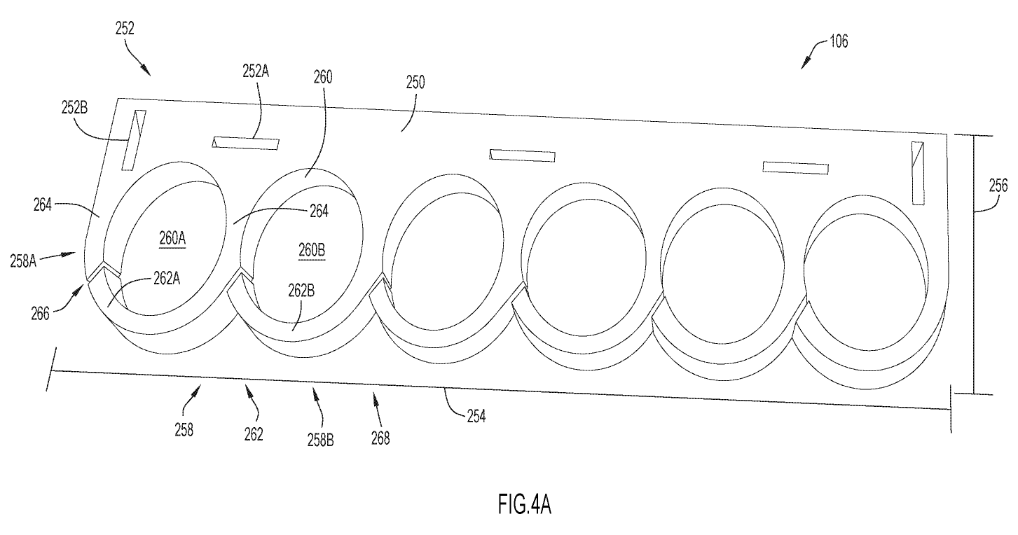

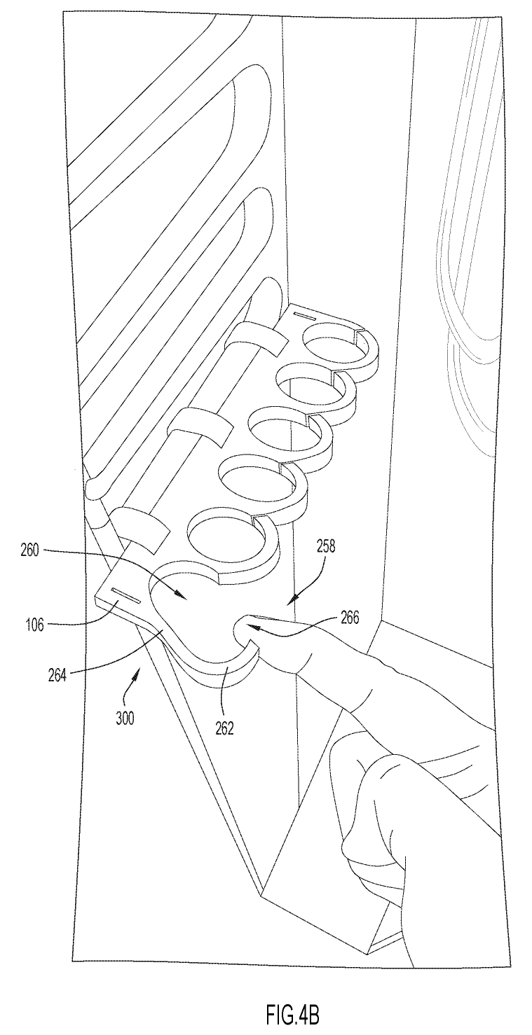

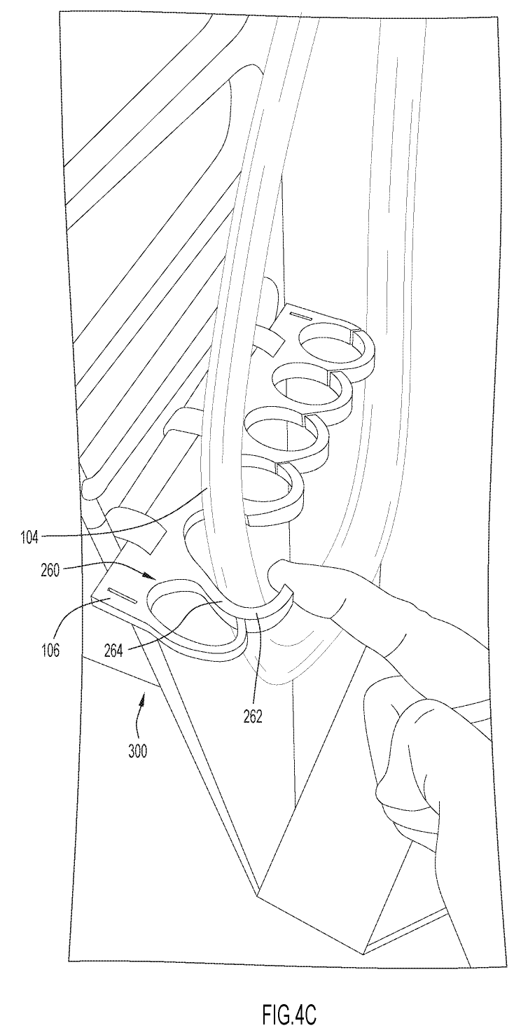

FIG. 4A is a front perspective view of a bracket 106 that is usable for routing and/or dressing cables 104. The bracket 106 includes a base 250 configured to couple to electrical equipment, such as a housing (e.g., the housing 152) and/or a cable management frame (e.g., the cable management frame 202). To this end, the base 250 includes multiple slits 252, which are configured to receive components (e.g., straps) used to couple the base 250 to the electrical equipment. The slits 252 are oriented in different manners to enable the bracket 106 to be positioned in different configurations and/or to enable the bracket 106 to accommodate and be attached to different configurations of electrical equipment, thereby increasing attachment versatility. By way of example, first slits 252A (e.g., horizontal slits) may extend at a center section of the base 250, and each first slit 252A may extend along a length 254 of the base. For instance, the first slits 252A may be collinear with one another. Meanwhile, second slits 252B (e.g., vertical slits) may extend at opposite ends of the base 250 such that the first slits 252A extend between the second slits 252B, and the second slits 252B may extend along a width 256 of the base 250. Therefore, the first slits 252A and second slits 252B are arranged at different angles and at different locations of the base 250 to increase attachment versatility. In some embodiments, each first slit 252A and second slit 252B extends approximately the same length. In other embodiments, however, a bracket 106 may include any arrangement of slits 252, with each slit 252 having any desirable shape, size, orientation, etc.

The bracket 106 also includes rings 258 that cooperatively define openings 260 with the base 250. Each opening 260 is configured to receive multiple cables 104, such that the rings 258 divide the cables 104 into individual groups via the openings 260, and the rings 258 separate each group from one another. By dividing the cables 104 into individual groups, the bracket 106 allows the cables 104 to be more easily manageable, distinguishable, and handled to facilitate organizing (e.g., routing) the cables 104 in a desirable manner.

Each ring 258 includes a flexible portion 262 and a fixed portion 264. The fixed portion 264 is fixed relative to the base 250, whereas the flexible portion 262 is configured to flex relative to the base 250 and the fixed portion 264. To this end, the flexible portion 262 is not directly connected to the fixed portion 264 toward which the flexible portion 262 arcuately extends. Instead, a space 266 separates the flexible portion 262 and the fixed portion 264 from one another to enable the flexible portion 262 to move and flex relative to the fixed portion 264. Flexing the flexible portion 262 adjusts an accessibility of a corresponding opening 260 (i.e., opens or closes an opening 260). In the depicted embodiment, a fixed portion 264 may at least partially define multiple openings 260 for adjacent rings 258. For example, a fixed portion 264 may serve as a base or stem from which a first flexible portion 262A extends to form a first opening 260A for a first ring 258A, and the same fixed portion 264 may also extend adjacent to a second flexible portion 262B to cooperatively define a second opening 260B for an adjacent second ring 258B. Meanwhile, the first ring 258A is also an end ring that includes its own dedicated fixed portion 264 that is rounded towards the first flexible portion 262A (i.e., a flexible portion 262 does not extend from the dedicated fixed portion 264) so that the dedicated fixed portion 264 has a continuous curvature between the base 250 and the first flexible portion 262A.

In the illustrated embodiment of FIG. 4A, the rings 258 are in closed configurations 268 in which the flexible portions 262 and fixed portions 264 are oriented to substantially enclose each opening 260. That is, the flexible portions 262 and the fixed portions 264 generally define each opening 260 as a closed loop in the closed configuration 268. Specifically, each flexible portion 262 extends arcuately from one fixed portion 264 toward another fixed portion 264. The closed configuration 268 substantially closes an opening 260 to retain a cable 104 within the opening 260. For example, a flexible portion 262 and a fixed portion 264 may cooperatively surround the cable 104 to loosely hold or enclose the cable 104 within the opening 260, with the “loosely” holding allowing a cable 104 to be easily moved through the opening 260 and/or removed from the opening 260, as discussed above. In some embodiments, in the closed configuration 268, a ring 258 forms a circular or ovular loop having a diameter or major axis of approximately 30 millimeters (mm) to 40 mm and/or a minor axis of approximately 20 mm to 30 mm to loosely hold cables 104 therein. However, a ring 258 may form any other shape in additional or alternative embodiments to loosely hold cables 104 therein.

Each of FIGS. 4B and 4C illustrates the bracket 106 with a ring 258 in an open configuration 300 in which a flexible portion 262 of one of the rings 258 (e.g., an end ring) is flexed relative to a corresponding fixed portion 264 (e.g., dedicated fixed portion) to open up its opening 260. For example, the flexible portion 262 is configured to flex in response to a sufficient force (e.g., a manually applied force). The open configuration 300 increases a size of the space 266 to enable a cable 104 to pass and be inserted into and/or removed from the opening 260. Thus, the open configuration 300 enables the cable 104 to be routed through the opening 260.

In some embodiments, the flexible portion 262 is composed of a resilient flexible material (e.g., thermoplastic polyurethane) that is naturally urged toward closing the opening 260. As an example, flexing the flexible portion 262 relative to the fixed portion 264 may elastically deform the resilient flexible material. Thus, absent a sufficient force applied to the flexible portion 262, the flexible portion 262 biases the ring 258 toward the closed configuration 268. Consequently, the rings 258 are maintained in the closed configuration 268 (e.g., to retain cables 104 within the openings) unless a sufficient force is applied.

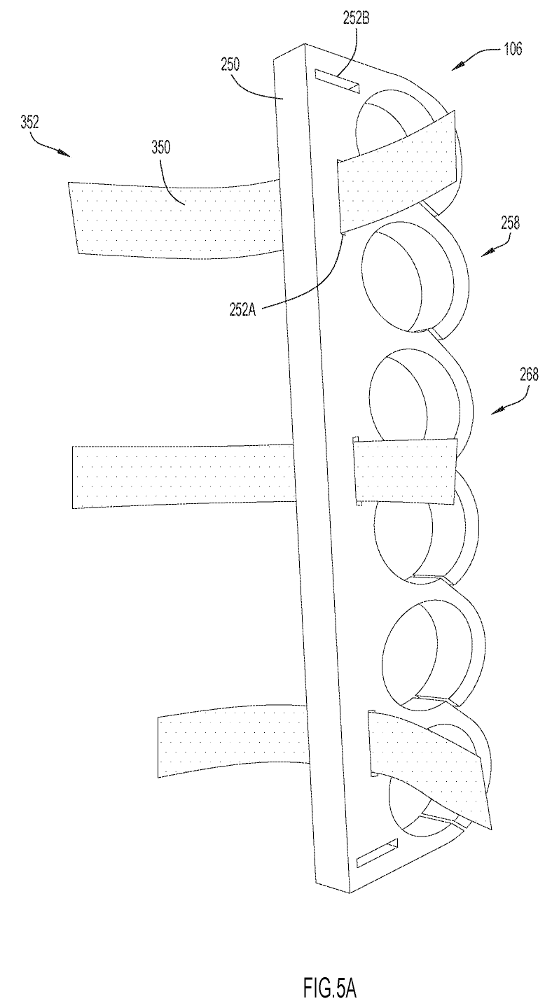

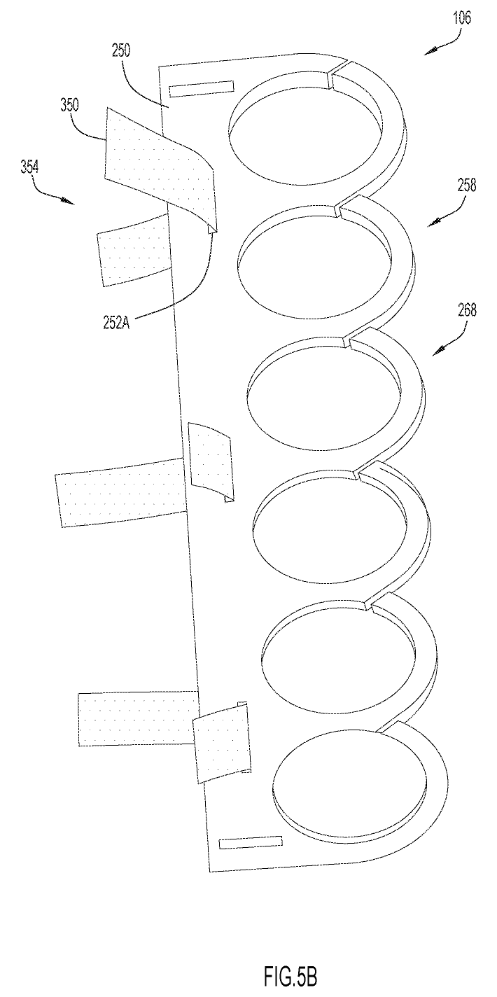

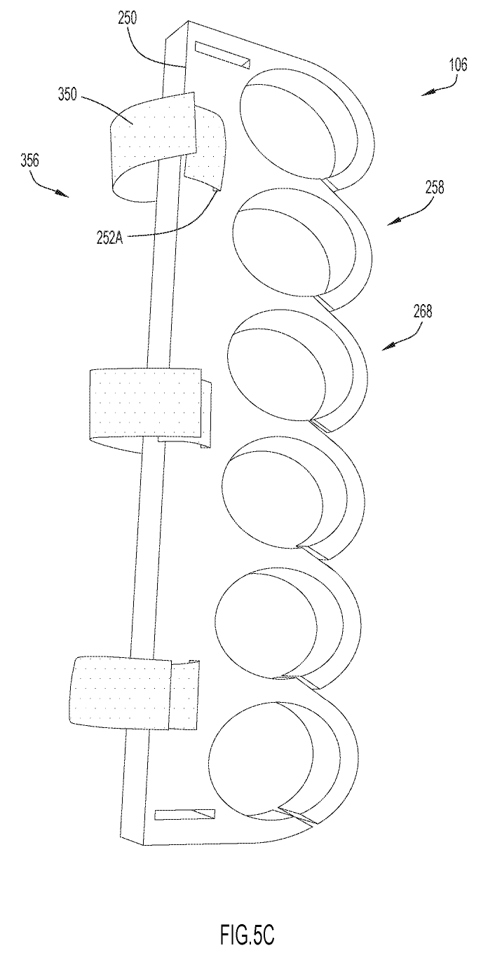

FIGS. 5A-5C are each a top perspective view of the bracket 106 with the rings 258 in the closed configuration 268, and straps 350 (e.g., hook-and-loop fasteners) are inserted through the first slits 252A of the base 250 of the bracket 106. The straps 350 are used to couple the bracket 106 to electrical equipment. FIG. 5A illustrates the straps 350 in an open configuration 352, FIG. 5B illustrates the straps 350 in a partially closed configuration 354, and FIG. 5C illustrates the straps 350 in a closed configuration 356. The open configuration 352 of the straps 350 enables the straps 350 to be inserted through the first slits 252A, and the closed configuration 356 blocks the straps 350 from being removed from the first slits 252A, thereby securing the straps 350 to the bracket 106. The first slits 252A also enable the straps 350 to be readily removed while the straps 350 are in the open configuration 352. Thus, the first slits 252A enable the bracket 106 to be removably coupled to electrical equipment via the straps 350 by looping the straps 350 through the first slits 252A and around the electrical equipment. It should be noted that the second slits 252B provide similar benefits to enable the bracket 106 to be coupled to and decoupled from electrical equipment via the straps 350. That is, a respective strap 350 may be looped through each second slit 252B (or a single strap 350 may be looped through multiple second slits 252B) and around the electrical equipment to removably couple the bracket 106 to the electrical equipment.

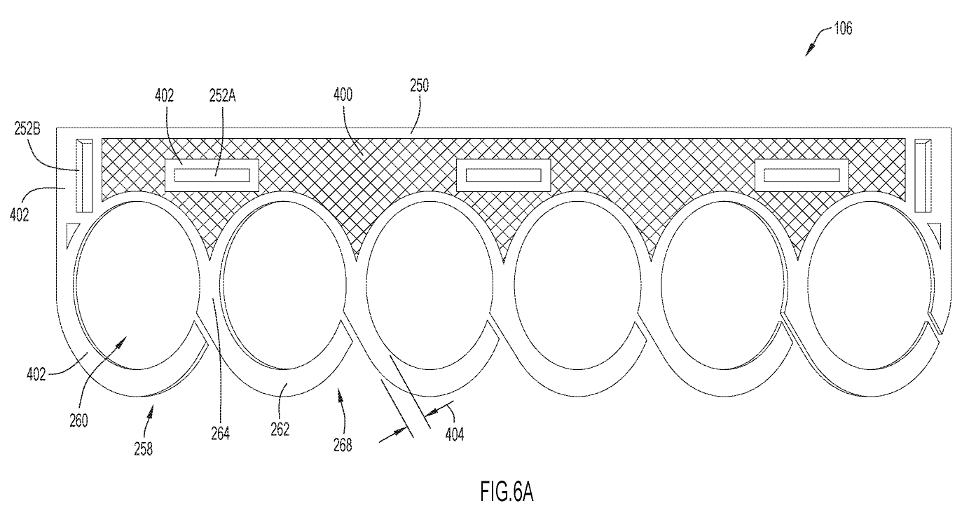

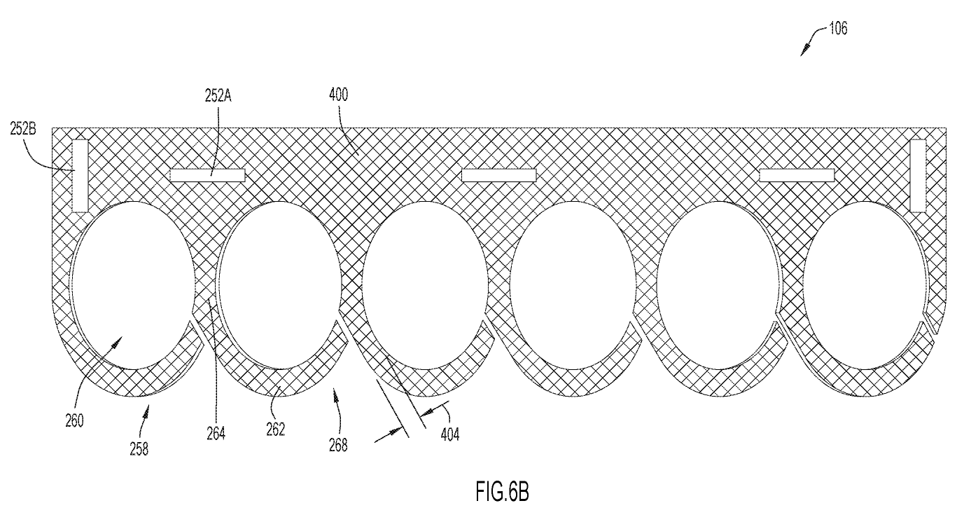

FIGS. 6A and 6B are each cross-sectional views of the bracket 106 to illustrate example internal structure of the bracket 106. The embodiment of the bracket 106 of FIG. 6A includes webbing 400 within a portion of the base 250. Additionally, the rings 258 and portions of the base 250 surrounding slits 252 of the base 250 include a material fill 402. Meanwhile, the embodiment of the bracket 106 of FIG. 6B includes webbing 400 in the base 250 and in the rings 258.

The internal structure of the bracket 106 affects the rigidity and flexibility thereof. Thus, the bracket 106 may be controllably manufactured to provide desirable rigidity/flexibility properties. As an example, the base 250 may be more densely filled with material to provide a sufficient rigidity for attachment to electrical equipment and to resist flexure while a force is applied to a flexible portion 262 to flex the flexible portion 262. As another example, the flexible portion 262 may be less densely filled with material to provide a sufficient flexibility to flex in response to a sufficiently applied force, while also resisting undesirable flexure (e.g., during contact with cables 104) to retain cables 104 in the openings 260. However, the flexible portion 262 may also be sufficiently densely filled with material to provide resiliently flexible properties that urge the flexible portion 262 to close a corresponding opening 260 absent the sufficiently applied force and/or to withstand the forces (e.g., by having a sufficiently high yield to avoid plastic deformation) applied thereto over time. For instance, an infill of the rings 258 may be between 30% and 50% filled with material, with a greater amount being at the fixed portions 264, which may be similar to or less dense than an infill of the base 250. Additionally or alternatively, the flexible portion 262 is manufactured to have a thickness 404 that provides desirable flexibility properties. For example, the thickness 404 of each flexible portion 262 is between 3 mm and 7 mm. In some embodiments, the thickness 404 of the flexible portions 262, rather than the infill therein, is controlled to provide the desirable flexibility properties of the flexible portions 262. Indeed, the thickness 404 of the flexible portions 262 may provide desirable flexibility of the flexible portions 262 regardless of the infill (e.g., density of material) of the flexible portions 262.

To this end, the material fill of the bracket 106 of FIG. 6A and the webbing 400 of the bracket 106 of FIG. 6B in the rings 258 are selectively arranged to provide the desirable flexibility thereof. Similarly, the material fill of the bracket 106 of FIG. 6A and the webbing 400 of the bracket 106 of FIG. 6B surrounding the slits 252 are selectively arranged to provide desirable flexibility properties, such as to permit some amount of flexibility to enable accommodation of the straps 350 used to couple the bracket 106 to electrical equipment. To reiterate, however, the internal arrangements depicted in FIGS. 6A and 6B are merely examples, and other embodiments can include any desirable internal structures that facilitate the features discussed herein.

In some embodiments, the bracket 106 is manufactured via additive manufacturing, such as three-dimensional printing. In additional or alternative embodiments, the bracket 106 is manufactured via a molding technique. In further embodiments, the bracket 106 is manufactured via subtractive manufacturing, such as machining. Any of these manufacturing techniques may controllably implement the internal structure of the bracket 106 to provide desirable flexibility and rigidity properties to enable the bracket 106 to attach to electrical equipment and retain cables 104 for management/dressing.

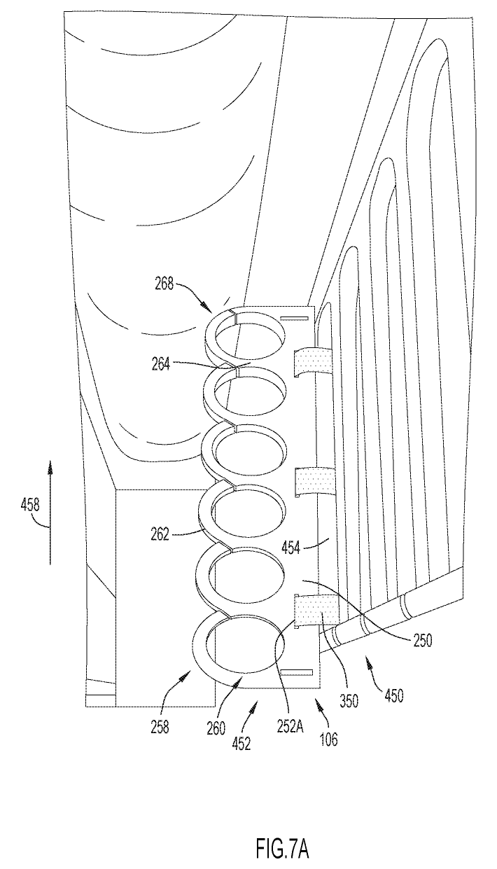

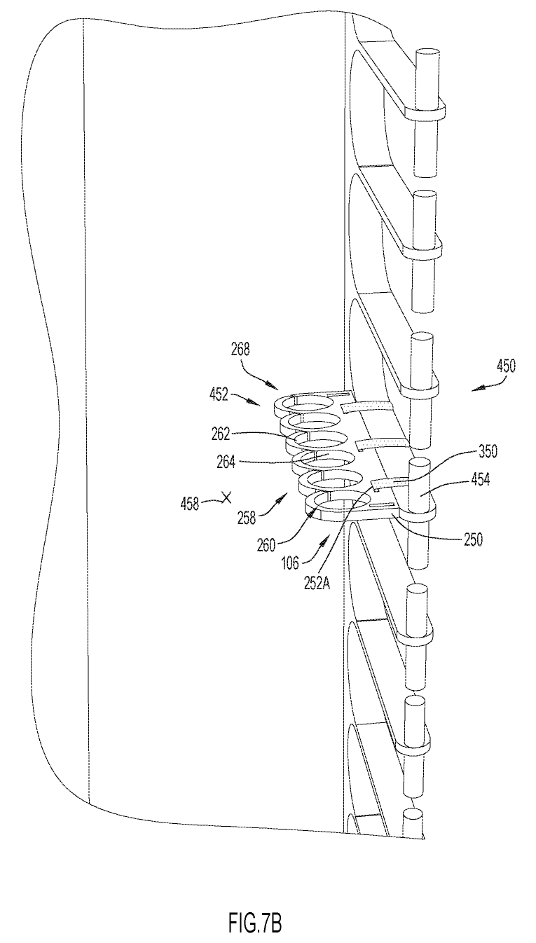

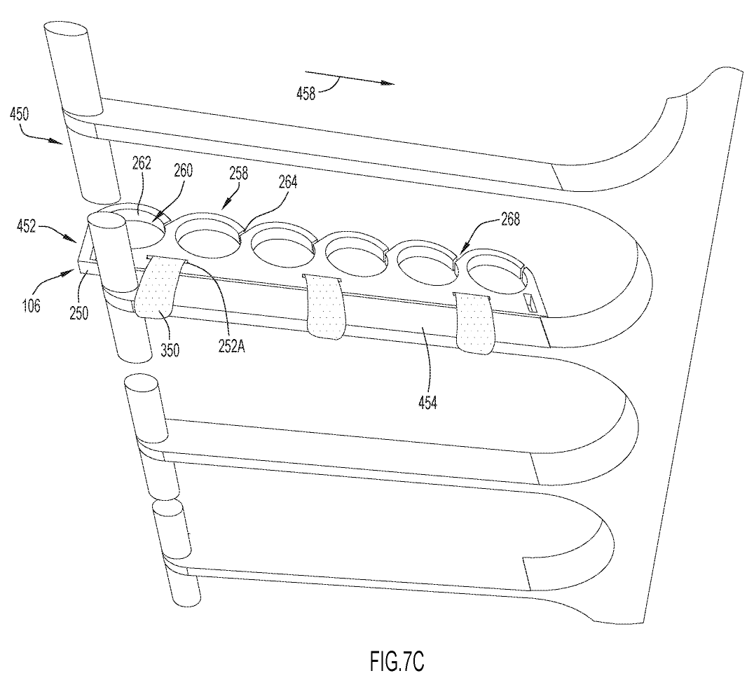

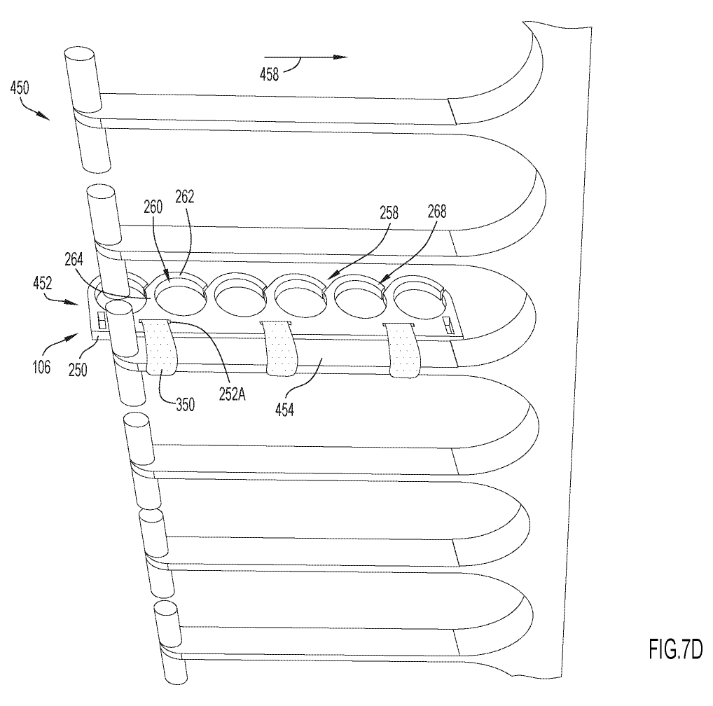

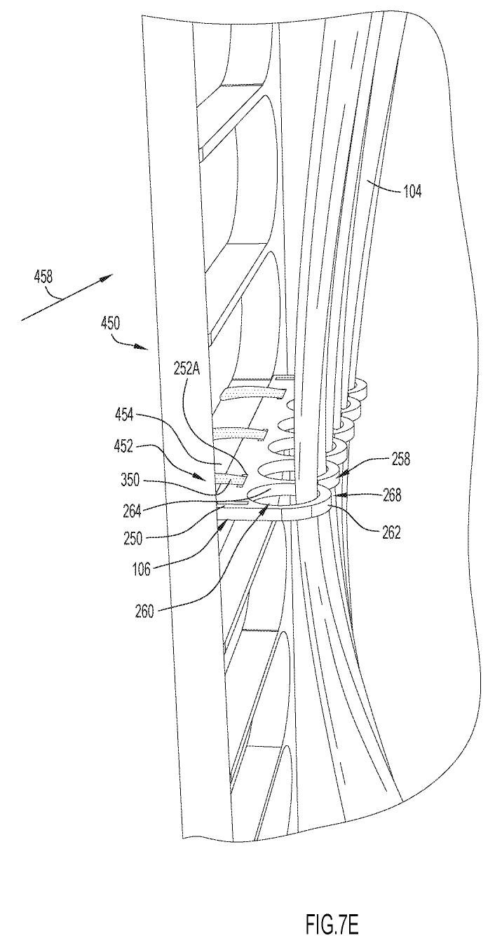

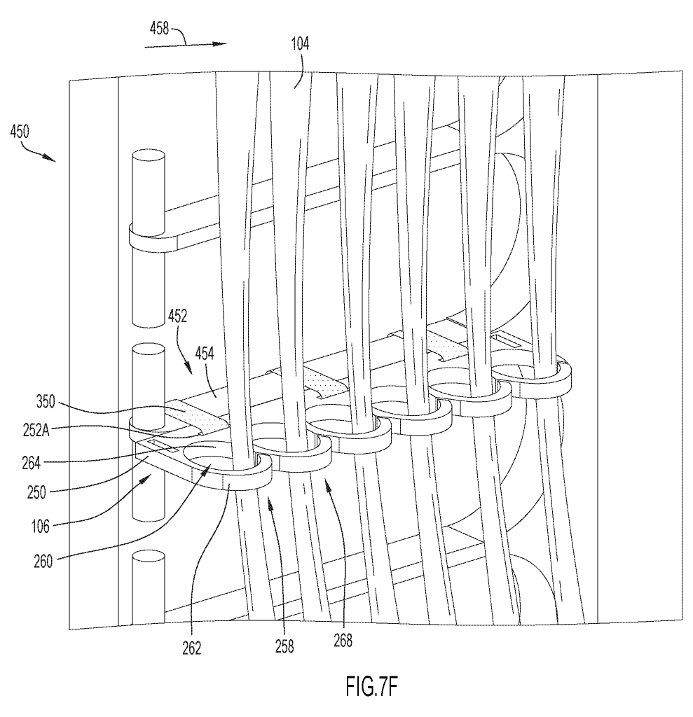

FIGS. 7A-7F each illustrate a bracket 106 attached to electrical equipment 450, such as a vertical cable manager, in a first configuration 452. In the first configuration 452, straps 350 are inserted through first slits 252A of a base 250 of the bracket 106 to attach to the bracket 106, and the straps 350 loop and enclose a rail 454 (e.g., a server rack rail) of the electrical equipment 450 to attach to the rail 454, thereby coupling the bracket 106 to the rail 454 in its closed configuration 356. Because each strap 350 encloses a common rail 454 in the illustrated first configuration 452, the first configuration 452 may be considered a single rail configuration in which the bracket 106 (e.g., the length 254 of the bracket 106) extends along a single rail 454. Such a first configuration 452 positions the rings 258 and openings 260 of the bracket 106 side-by-side along a span of the rail 454, such as along a direction 458 extending into a depth of the electrical equipment 450, thereby enabling groups of cables 104 separated by the rings 258 and openings 260 to be positioned alongside one another along the span of the rail 454.

FIGS. 7E and 7F illustrate the bracket 106 with cables 104 extending through the openings 260. As discussed herein, the bracket 106 includes rings 258 that each include a flexible portion 262 and a fixed portion 264, and the flexible portion 262 is configured to flex relative to the base 250 and the fixed portion 264 to open an opening 260 and enable a cable 104 to be inserted into the opening 260. The first configuration 452 of the bracket 106 may fix a position of the bracket 106 to enable a sufficient force to be applied more easily to flex a flexible portion 262 to increase accessibility of the opening 260 and enable the cable 104 to be inserted into the opening 260. Additionally, absent the sufficient force, the flexible portion 262 is urged to enclose the opening 260 to retain the cable 104 within the opening 260 while the bracket 106 remains attached to the electrical equipment 450. For instance, in the closed configuration 268 of the rings 258, the flexible portion 262 may surround the cables 104 routed through the corresponding opening 260 to block movement of the cable 104 out of the opening 260. At the same time, the openings 260 do not closely conform to or capture the cables 104 installed therein and, thus, allow the cables 104 to be pulled through the bracket 106 without adjusting, operating, and/or removing the bracket 106 (e.g., to increase a size of the openings 260).

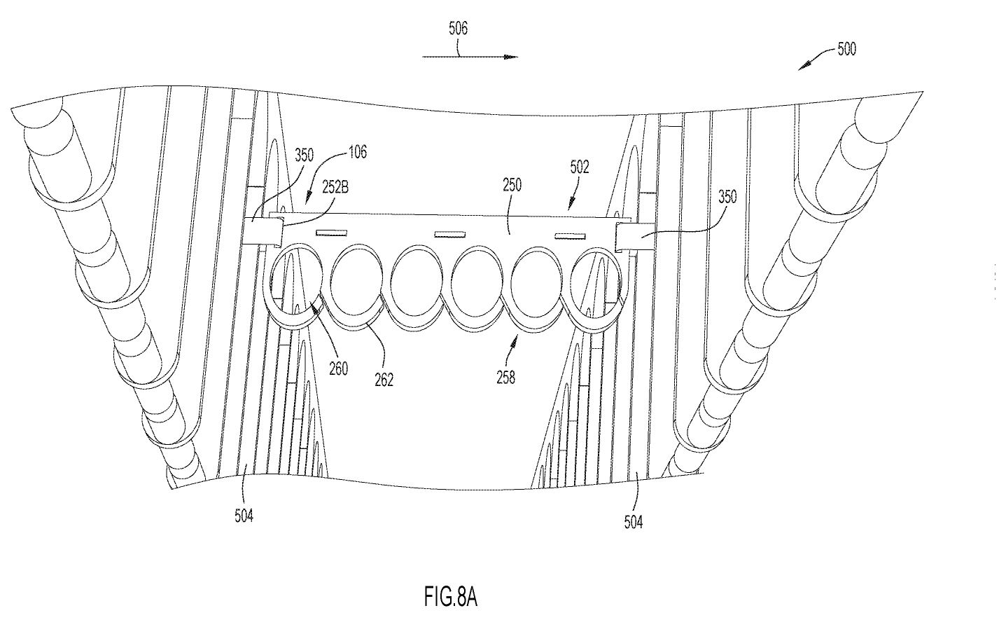

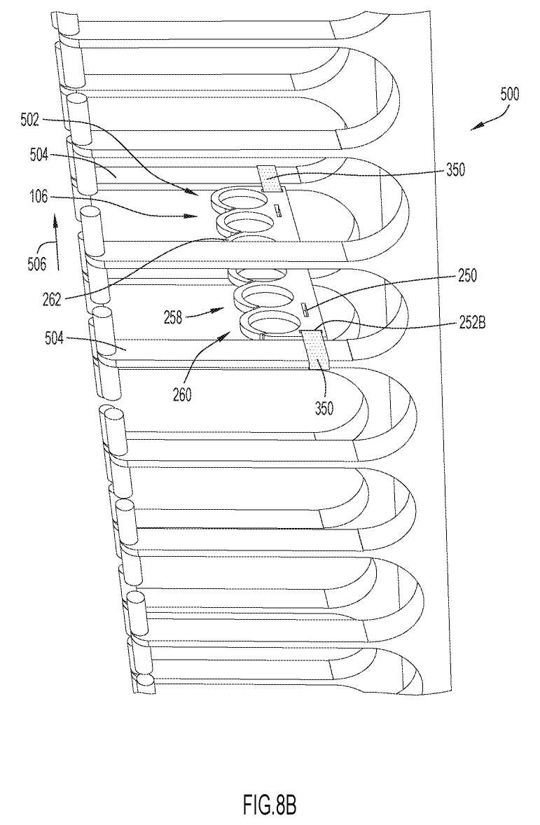

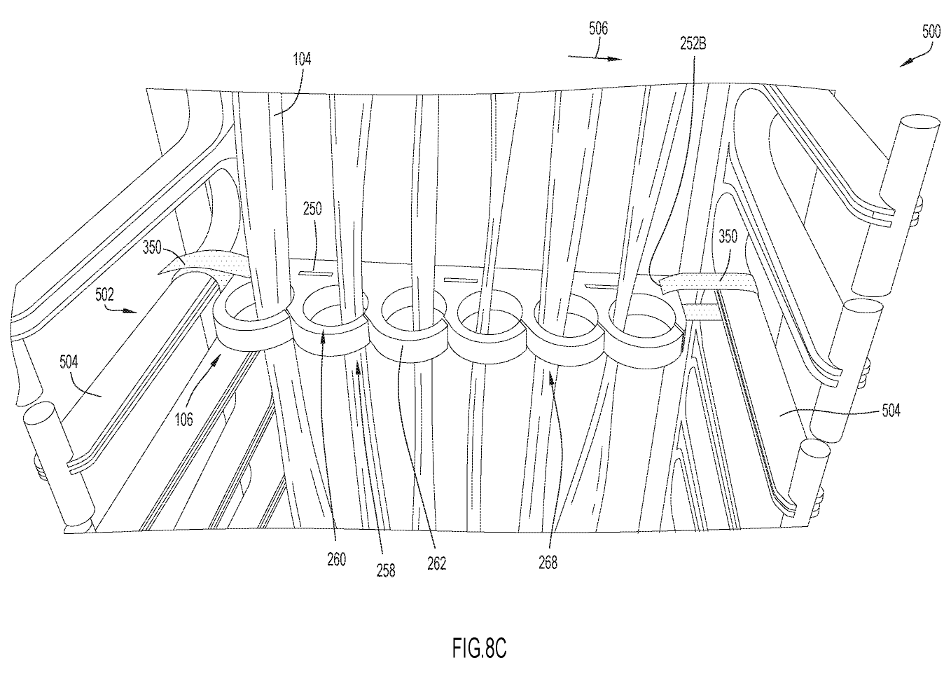

FIGS. 8A-8C each illustrate a bracket 106 attached to electrical equipment 500, such as a vertical cable manager, in a second configuration 502. In the second configuration 502, straps 350 are inserted through second slits 252B of a base 250 of the bracket 106 to attach to the bracket 106, and the straps 350 are wrapped around respective rails 504 of the electrical equipment 500 to attach to the respective rails 504, thereby coupling the bracket 106 to the respective rails 504. Because each strap 350 encloses a different rail 504 in the illustrated second configuration 502, the second configuration 502 may be considered a multiple rail configuration in which the bracket 106 extends between multiple rails 504. Such a second configuration 502 positions the rings 258 and openings 260 of the bracket 106 side-by-side between the rails 504, such as along a direction 506 extending across a width of the electrical equipment 500, thereby enabling groups of cables 104 separated by the rings 258 and openings 260 to be positioned alongside one another between the rails 504.

FIG. 8C illustrates the bracket 106 with cables 104 extending through the openings 260. The second configuration 502 of the bracket 106 may also facilitate inserting the cable 104 into the opening 260 by fixing a position of the bracket 106. In turn, fixing the bracket 106 may enable a sufficient force to be applied to the flexible portions 262 to flex a flexible portion 262 of the bracket 106 to open an opening 260 and enable a cable 104 to be inserted into the opening 260. The rings 258 of the illustrated bracket 106 are in a closed configuration 268 in which the flexible portions 262 are urged closed to surround and retain the cables 104 within the openings 260.

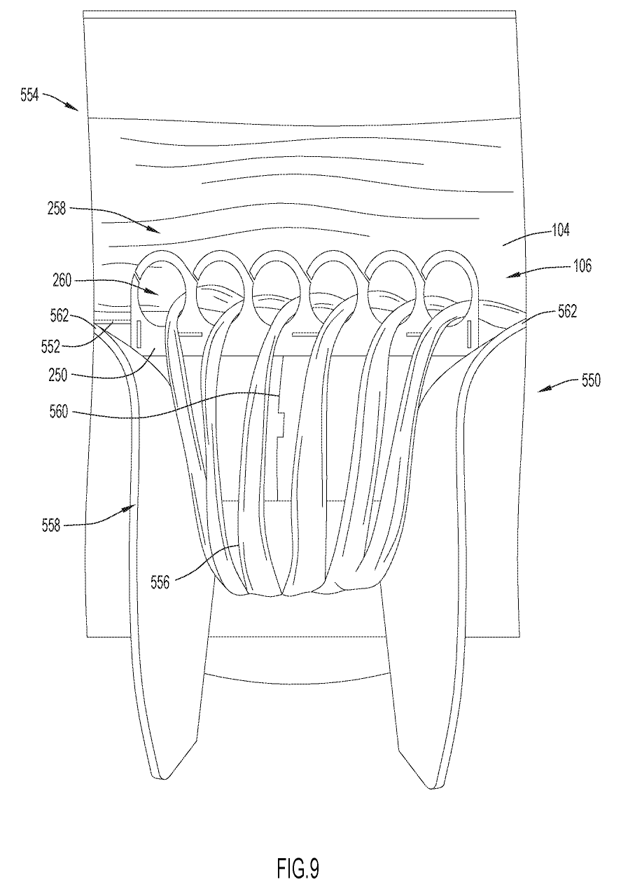

FIG. 9 is a top perspective view of electrical equipment 550 with cables 104. The electrical equipment 550 includes a first surface 552 (e.g., of a first channel 554) and a second surface 556 (e.g., of a second channel 558). The first surface 552 and the second surface 556 extend transverse to one another (i.e., are not planar or parallel to one another). For instance, the first surface 552 may extend horizontally, whereas the second surface 556 may extend vertically. Cables 104 are routed along the first surface 552, and a subset of the cables 104 are routed from the first surface 552 to the second surface 556 via a transition surface 560 extending between the first surface 552 and the second surface 556. For instance, the subset of cables 104 is routed along the second surface 556 to electrically connect to electrical components disposed adjacent to the second surface 556, whereas a remainder of the cables 104 continues to extend along the first surface 552 to electrically connect to electrical components that are disposed farther away from the second surface 556. In some embodiments, the first surface 552 and the second surface 556 are surfaces of the same component, such as a housing, of the electrical equipment 550. In alternative embodiments, the first surface 552 and the second surface 556 are surfaces of different components of the electrical equipment 550. For example, the first surface 552 may be a surface of a housing of the electrical equipment 550, whereas the second surface 556 may be a surface of a cable management frame attached to the housing.

A bracket 106 is used to help transition (e.g., bend, curve) the subset of cables 104 from the first surface 552 to the second surface 556, such as to help with routing and organizing the subset of cables 104 as they extend along the second surface 556. For example, the bracket 106 may be positioned at the transition surface 560, and cables 104 may be inserted through 260 openings of the bracket 106 to divide and separate the cables 104 into different groups prior to being routed to the second surface 556. In the illustrated embodiment, the bracket 106 is positioned such that the rings 258 extend at least partially in overlap with the first surface 552 to separate the subset of cables 104 into groups at the first surface 552 (i.e., before the subset of cables 104 extend over the transition surface 560 or over the second surface 556) to help separate the subset of cables 104 as they transition toward the second surface 556. However, in alternative embodiments, the bracket 106 is positioned such that the rings 258 extend at least partially in overlap with the transition surface 560 or the second surface 556.

The illustrated bracket 106 is coupled to the electrical equipment 550 by engaging the base 250 of the bracket 106 with a part of the electrical equipment 550. In particular, the electrical equipment 550 includes walls 562 extending along the first surface 552 and the transition surface 560, and the base 250 is wedged between opposite walls 562 to secure or removably couple the base 250 via an interference fit. However, in additional or alternative embodiments, the base 250 may be coupled to the electrical equipment 550 in any other suitable manner, such as via a strap, a fastener, and the like.

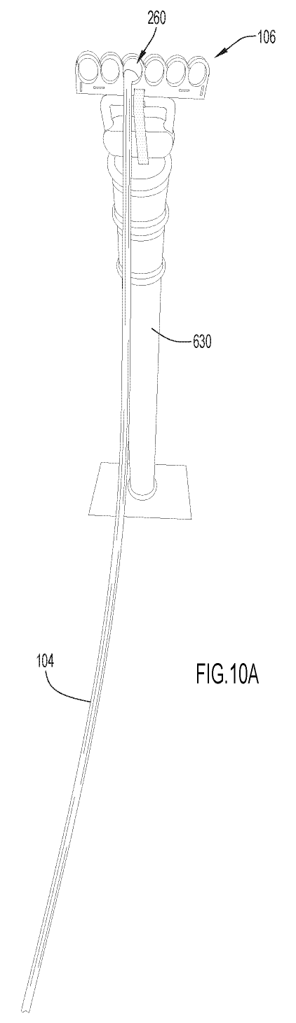

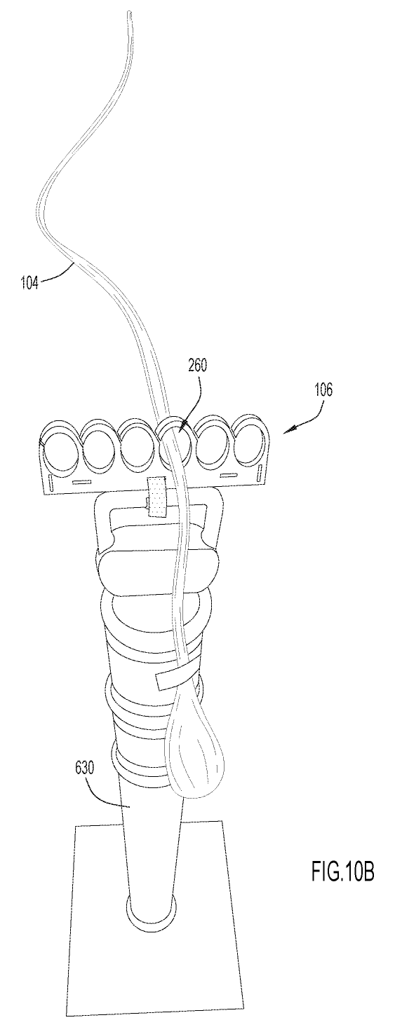

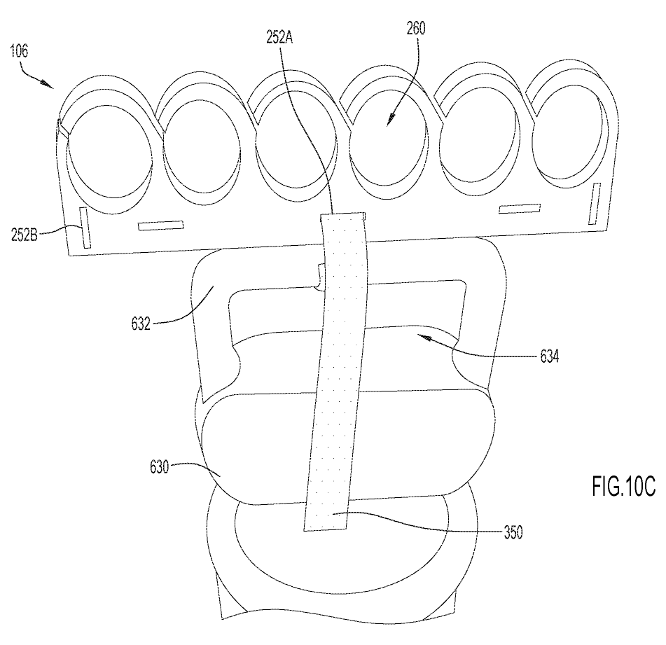

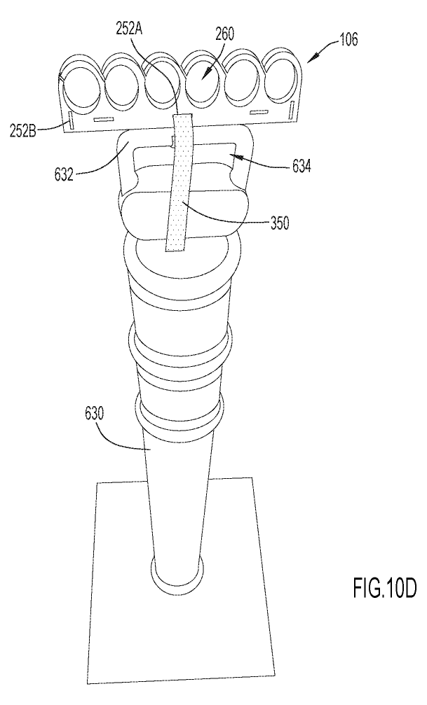

FIGS. 10A-10D illustrate another possible application of the bracket 106. In particular, the bracket 106 may be used to facilitate rollout of cables 104, during which the cables 104 are extended out and unraveled (e.g., from a spool) to reduce slack. Each of FIGS. 10A and 10B illustrates the bracket 106 fixed to a mount 630, such as a pylon, with cables 104 extending through openings 260 of the bracket 106. The bracket 106 helps maintain a position of a portion of the cables 104 to facilitate rollout. By way of example, the bracket 106 may provide tension to block certain unwanted movement (e.g., re-curling) of the cables 104 and allow the cables 104 to continue to be pulled through the openings 260 for rollout. Additionally or alternatively, the bracket 106 may organize cables 104 during rollout and/or block movement of a portion of the cables 104 to enable the cables 104 to be routed desirably during rollout. Although the cables 104 are extended through a single opening 260 in FIGS. 10A and 10B, it should be noted that respective groups of cables 104 may be extended through different openings 260 of the same bracket 106 or of a different bracket 106 during rollout.

FIGS. 10C and 10D show details regarding attaching the bracket 106 to the mount 630. In the illustrated example, the mount 630 includes a segment 632 defining a loop 634. A strap 350 extends through a slit 252 (e.g., one of the first slits 252A) of the bracket 106 and encloses the segment 632 (i.e., extends through the loop 634 to loop around the segment 632) to couple the bracket 106 to the mount 630. The bracket 106 may be configured to couple to the mount 630 in an additional or alternative manner, such as using a different slit 252 (e.g., one of the second slits 252B), in other arrangements.

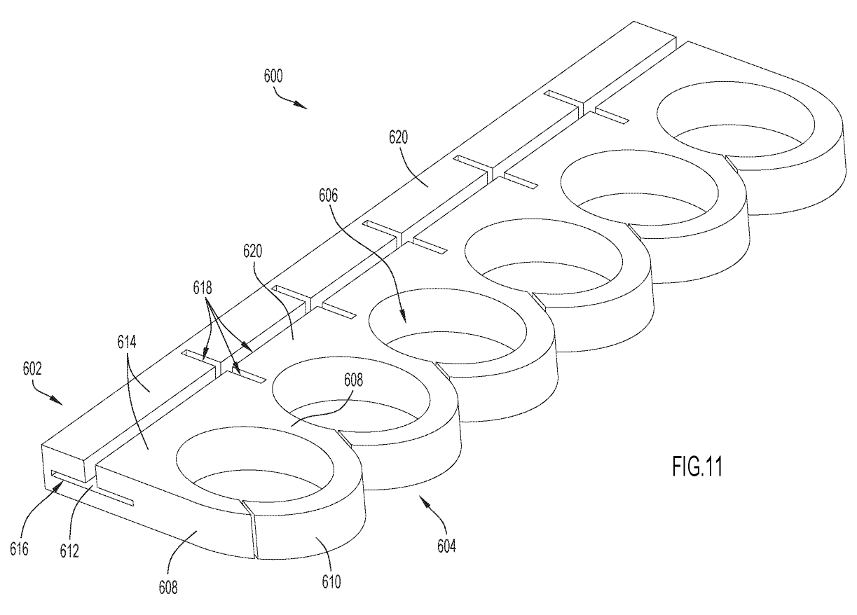

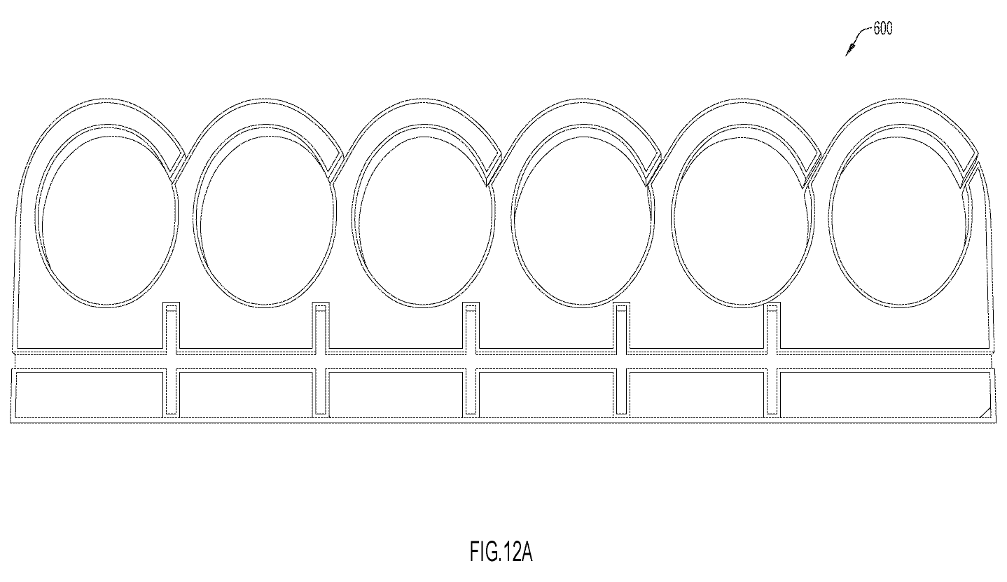

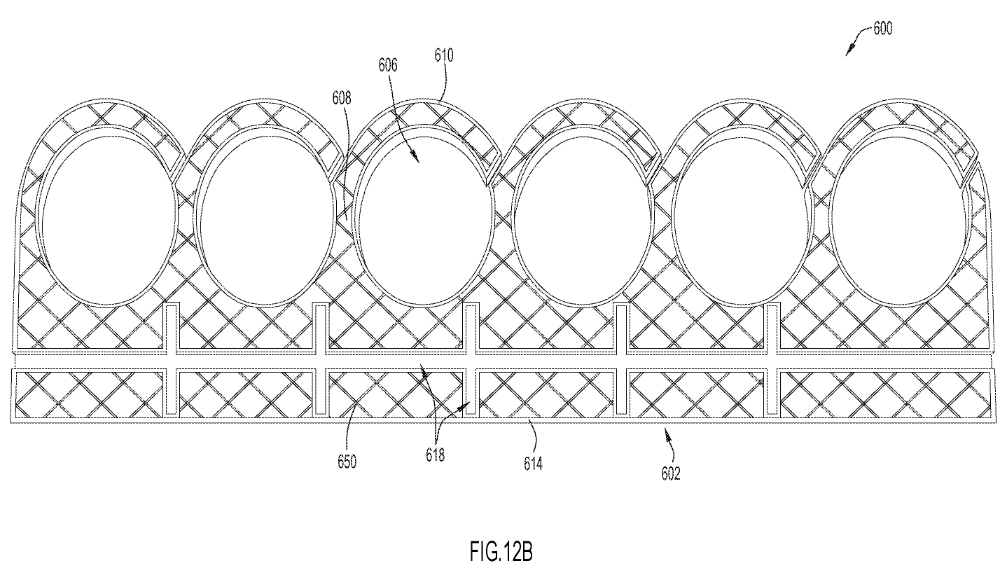

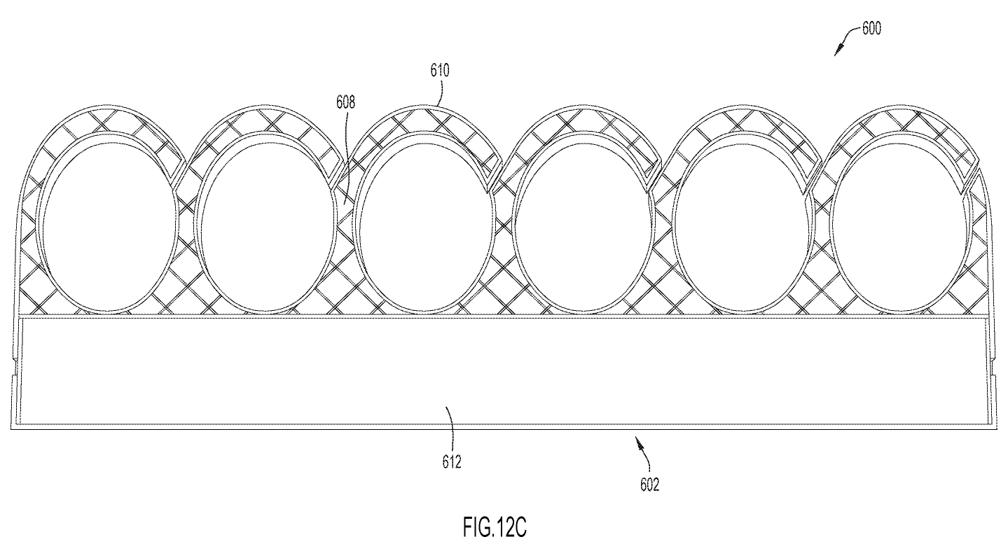

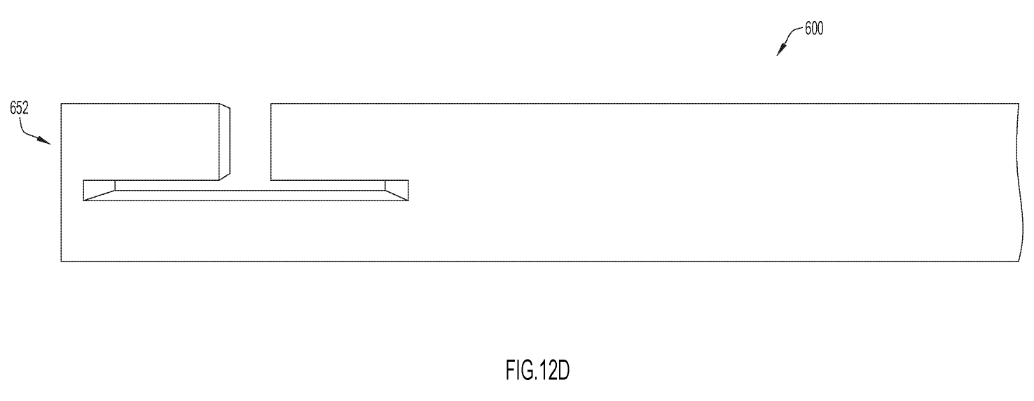

A different embodiment of a bracket may be used and provide similar advantages discussed herein. FIGS. 11 and 12A-12D illustrate a bracket 600 having a different design than the bracket 106 to provide a different attachment mechanism to electrical equipment. However, the bracket 600 includes features similar to those of the bracket 106 for separating cables 104 into groups and loosely holding the cables 104 to allow for ease of attaching/detaching and moving through the bracket 106. Therefore, the bracket 600 may provide similar benefits and advantages as those discussed with respect to the bracket 106.

FIG. 11 is a top perspective view of the bracket 600. The bracket 600 includes a base 602 and rings 604 defining openings 606 configured to receive and separate cables 104. In particular, fixed portions 608 extend from the base 602, and a respective flexible portion 610 extends from each fixed portion 608 toward an adjacent fixed portion 608 such that the fixed portions 608 and flexible portions 610 cooperatively surround and define the openings 606. Each flexible portion 610 is configured to flex relative to the fixed portions 608 to open and increase access to the openings 606 to enable a cable 104 to be routed into or out of the openings 606. Moreover, each flexible portion 610 is urged toward closing the openings 606 absent a force imparted to flex the flexible portion 610.

The base 602 is arranged to enable the bracket 600 to be secured or removably coupled to electrical equipment without the use of straps or any additional components (e.g., a fastener). In particular, the base 602 includes a main body 612 and lips 614 extending over the main body 612 to form a gap 616 between the lips 614 and the main body 612. Moreover, cutouts 618 (e.g., slits, slots, notches) are formed into the lips 614, thereby forming particular shapes of the lips 614. For example, the cutouts 618 may form rectangular segments 620 of the lips 614. This shaping of the lips 614 enables the base 602 to interface with a correspondingly shaped part of the electrical equipment to couple to the electrical equipment. For instance, the rectangular segments 620 may be configured to be positioned and compressed within receptacles of the electrical equipment. As another example, extensions (e.g., fingers) of the electrical equipment may be configured to be positioned within the cutouts 618 and/or the gap 616 to cause the lips 614 to compress against and secure to the extensions. In either case, the base 602 is configured to secure or removably couple to the electrical equipment via an interference fit (e.g., a compressive force) without having to use an additional component, such as a strap, dedicated to attach the bracket 600 to the electrical equipment. In other embodiments, however, the connection need not be an interference and could be a snap fit, slip fit, detent coupling, or other such coupling that does not require fasteners or additional components (e.g., straps).

FIGS. 12A-12D illustrate different layers of the bracket 600, showing greater details of the structure of the bracket 600. FIG. 12A is a top view of the bracket 600, illustrating the exterior of the bracket 600. The exterior of the bracket 600 is relatively smooth (e.g., does not include webbing), which may provide ease of placement and/or cover internal structure. FIG. 12B is a top cross-sectional view of the bracket 600 illustrating internal structure of the lips 614, flexible portions 610, and fixed portions 608. As shown, the bracket 600 has webbing 650, which may help the flexible portions 610 flex to adjust the openings 606. The lips 614 also include webbing 650 to help the lips 614 flex. For instance, the webbing 650 may help the lips 614 flex to open a size of some of the cutouts 618, which enables the lips 614 to extend into part of the electrical equipment and/or enable part of the electrical equipment to extend into the cutouts 618. However, the lips 614 are also resiliently flexible and are urged toward closing the cutouts 618 absent a force imparted onto the lips 614. This provides a compressive force that helps secure or removably couple the base 602 onto the electrical equipment, thereby attaching the bracket 600 to the electrical equipment via an interference fit.

FIG. 12C is another top cross-sectional view of the bracket 600, which illustrates an interior of the fixed portions 608, the flexible portions 610, and the main body 612. Unlike the lips 614, the main body 612 does not include any webbing. Instead, the main body 612 has a dense material infill. This prevents or at least discourages the main body 612 from flexing. Instead, the main body 612 acts as a fixed part about which the lips 614 are configured to flex. Thus, the main body 612 helps retain the shape of the bracket 600, provide support for the lips 614, and/or increase structural rigidity of the bracket 600, while also enabling the base 602 to couple to the electrical equipment by flexing the lips 614.

FIG. 12D is a side cross-sectional view of the bracket 600. As shown, the bracket 600 includes multiple layers 652 stacked against one another. By way of example, the bracket 600 is formed via additive manufacturing to individually and sequentially form each layer 652. Additionally or alternatively, the bracket 600 is formed via a molding technique, a subtractive manufacturing, and/or any other suitable technique to provide the shape of the bracket 600 and its properties (e.g., resilient flexibility) to secure or removably couple to electrical equipment and to loosely hold cables 104 within the openings 606.

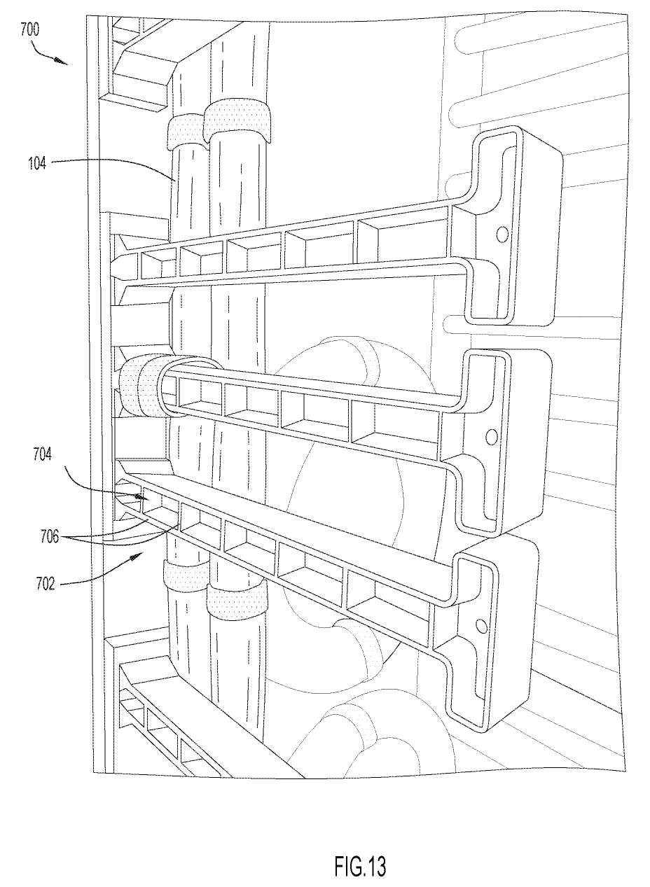

FIG. 13 is a side perspective view of electrical equipment 700 to which the bracket 600 may attach. Specifically, the electrical equipment 700 includes rails 702, which may be used to route cables 104 (e.g., by draping the cables 104 over the rails 702). Each rail 702 includes receptacles 704 configured to receive the lips 614 of the bracket 600. For example, the rail 702 includes walls 706 that define the receptacles 704 and separate adjacent receptacles 704 from one another. Each receptacle 704 is configured to receive a respective rectangular segment 620 of the lips 614 such that a subset of the walls 706 extend into corresponding cutouts 618 of the base 602 of the bracket 600. While the lips 614 are inserted into the receptacle 704, the rectangular segments 620 compress against the walls 706 (e.g., by urging to close the cutouts 618), thereby securing the base 602 to the rail 702 via an interference fit. The compressive force imparted by the rectangular segment 620 against the walls 706 may sufficiently secure or removably couple the bracket 600 to the electrical equipment 700 without having to use an additional securement component, such as a strap, thereby improving ease of coupling the bracket 600 to and/or decoupling the bracket 600 from the electrical equipment.

It is also to be understood that the sector plate described herein, or portions thereof may be fabricated from any suitable material or combination of materials, such as metals or synthetic materials including, but not limited to, plastic, rubber, derivatives thereof, and combinations thereof. It is also intended that the present disclosure cover modifications and variations of this concept. For example, it is to be understood that terms such as “left”, “right”, “top”, “bottom”, “upper”, “lower”, “front”, “rear”, “side”, “height”, “length”, “width” “interior”, “exterior,” “inner”, “outer” and the like as may be used herein, merely describe points of reference and do not limit the present disclosure to any particular orientation or configuration.

Finally, when used herein, the term “comprises” and its derivations (such as “comprising”, etc.) should not be understood in an excluding sense, that is, these terms should not be interpreted as excluding the possibility that what is described and defined may include further elements, steps, etc. Meanwhile, when used herein, the term “approximately” and terms of its family (such as “approximate”, etc.) should be understood as indicating values very near to those which accompany the aforementioned term. That is to say, a deviation within reasonable limits from an exact value should be accepted, because a skilled person in the art will understand that such a deviation from the values indicated is inevitable due to measurement inaccuracies, etc. The same applies to the terms “about” and “around” and “substantially”.

1. A bracket for managing cables, the bracket comprising:
a base configured to be removably coupled to electrical equipment; and
a plurality of rings cooperatively defining a plurality of openings configured to separate cables into groups, wherein each ring of the plurality of rings comprises:
a fixed portion extending from the base; and
a flexible portion extending from the fixed portion and configured to flex relative to the fixed portion to adjust a size of an opening of the plurality of openings.

2. The bracket of claim 1, wherein the base comprises a slit for removably coupling the base to the electrical equipment.

3. The bracket of claim 2, wherein the base comprises:
a main body; and
a lip extending over the main body, wherein the slit is formed into the lip and is configured to receive a portion of the electrical equipment, and the lip is configured to flex relative to the main body to compress against the portion of the electrical equipment to secure the base to the electrical equipment.

4. The bracket of claim 2, wherein the slit is configured to receive a strap that, once installed, encloses part of the base and the electrical equipment to secure the base to the electrical equipment.

5. The bracket of claim 1, wherein the flexible portion is urged toward closing the opening to loosely hold cables within the opening.

6. The bracket of claim 5, wherein the flexible portion comprises webbing to enable the flexible portion to elastically deform during flexure and urge the flexible portion toward closing the opening.

7. The bracket of claim 5, wherein the flexible portion comprises a material infill between 30% and 50% to enable the flexible portion to elastically deform during flexure and urge the flexible portion toward closing the opening.

8. A system, comprising:
electrical equipment comprising an electrical component; and
a bracket configured to be removably coupled to the electrical equipment, wherein the bracket comprises a plurality of rings that each include a fixed portion and a flexible portion extending from the fixed portion such that the fixed portion and the flexible portion cooperatively define an opening configured to receive a cable for coupling to the electrical component, and the flexible portion is configured to flex relative to the fixed portion to adjust a size of the opening.

9. The system of claim 8, wherein the electrical equipment comprises a rail of a server rack.

10. The system of claim 9, wherein the rail comprises a plurality of walls defining a receptacle, and the bracket comprises a base configured to be inserted into the receptacle to secure the bracket to the rail.

11. The system of claim 10, wherein the base comprises a plurality of lips, a lip of the plurality of lips is configured to be inserted into the receptacle, and the plurality of lips is configured to compress against the plurality of walls of the rail to secure the bracket to the electrical equipment.

12. The system of claim 8, comprising a strap configured to secure the bracket to the electrical equipment.

13. The system of claim 8, wherein the electrical equipment comprises a vertical cable manager or a horizontal cable manager.

14. The system of claim 8, wherein the electrical equipment comprises a first surface and a second surface extending transverse to the first surface, and the bracket is positioned between the first surface and the second surface to route the cable from the first surface to the second surface.

15. A bracket for managing cables, the bracket comprising:
a base configured to secure to electrical equipment;
a first fixed portion extending from the base;
a second fixed portion extending from the base; and
a flexible portion extending from the first fixed portion toward the second fixed portion such that the first fixed portion, the second fixed portion, and the flexible portion cooperatively define an opening configured to receive cables, and the flexible portion is configured to flex relative to the first fixed portion to adjust a size of the opening.

16. The bracket of claim 15, comprising:
a third fixed portion extending from the base; and
an additional flexible portion extending from the second fixed portion toward the third fixed portion such that the second fixed portion, the third fixed portion, and the additional flexible portion cooperatively define an additional opening configured to receive cables, and the additional flexible portion is configured to flex relative to the second fixed portion to adjust a size of the additional opening.

17. The bracket of claim 15, wherein the base comprises a lip and a cutout formed into the lip, the cutout is configured to receive a portion of the electrical equipment, and the lip is configured to flex to close the cutout and compress against the portion of the electrical equipment to secure the base to the electrical equipment.

18. The bracket of claim 17, wherein the base comprises a main body, and the lip extends over the main body and is configured to flex relative to the main body.

19. The bracket of claim 18, wherein the lip comprises webbing to enable the lip to flex relative to the main body, and the main body does not comprise webbing.

20. The bracket of claim 15, wherein the flexible portion is composed of thermoplastic polyurethane.
